(19) United States
(12) Patent Application Publication
(10) Pub. No.: US 2025/0355062 A1
(43) Pub. Date: Nov. 20, 2025

(54) Testing Electrically Conductive Interconnections

(71) Applicant: AT&S Austria Technologie & Systemtechnik Aktiengesellschaft, Leoben (AT)

(72) Inventors: Diego LORENZONI, Novara (IT); Linfeng LU, Shanghai (CN); Jiajie DUANMU, Nantong City (CN)

(21) Appl. No.: 19/127,066

(22) PCT Filed: Oct. 19, 2023
(86) PCT No.: PCT/EP2023/079167

§ 371 Date: May 2, 2025

(30) Foreign Application Priority Data
Nov. 2, 2022 (CN) 202211362481.1
Nov. 2, 2022 (EP) 22205092.4
Jun. 1, 2023 (EP) 23176785.6

(51) Int. Cl. G01R 31/68; H01L 23/538

(52) U.S. Cl. CPC G01R 31/68; H01L 23/5386

(57) ABSTRACT

A component carrier, including: i) a stack comprising at least two electrically conductive layer structures and at least one electrically insulating layer structure; ii) a plurality of components provided in or on the stack; iii) a plurality of electrically conductive interconnections in the stack electrically connecting at least one electrically conductive layer structure and a respective component; and iv) a test region provided in a portion of the component carrier, the test region comprising at least one test component and at least one second electrically conductive interconnection, the test component having the area where the second electrically conductive interconnection is connected with the same mechanical/chemical features and/or the same position in the depth of the correspondent one of the plurality of components, the second electrically conductive interconnection having the same mechanical/chemical features and/or the same position in the depth of at least one of the plurality of electrically conductive interconnections, wherein connecting areas are exposed on same side of the component carrier, the areas being respectively electrically connected to the two extremities of the at least one second electrically conductive interconnection.

### CROSS REFERENCE TO RELATED APPLICATIONS

This application is a national stage application, filed under 35 U.S.C. § 371, of International Patent Application No. PCT/EP2023/079167, filed on Oct. 19, 2023, claiming priority of the Chinese Patent Application No. 202211362481.1, filed on Nov. 2, 2022, the European Patent Application No. 22205092.4, filed on Nov. 2, 2022, and of the European Patent Application No. 23176785.6, filed on Jun. 1, 2023, the disclosures of which are hereby incorporated by reference herein in their entirety.

### TECHNICAL FIELD

The disclosure relates to a component carrier with electrically conductive interconnections. Further, the disclosure relates to a method to check the quality of an electrically conductive interconnection of a component carrier.

Thus, the disclosure may relate to the technical field of component carriers such as printed circuit boards and IC substrates, in particular in the context of testing the reliability of electrically conductive interconnections.

### BACKGROUND

In the context of growing product functionalities of component carriers equipped with one or more electronic components and increasing miniaturization of such electronic components as well as a rising number of electronic components to be mounted on the component carriers such as printed circuit boards, increasingly more powerful array-like components or packages having several electronic components are being employed, which have a plurality of contacts or connections, with ever smaller spacing between these contacts. Removal of heat generated by such electronic components and the component carrier itself during operation becomes an increasing issue. At the same time, component carriers shall be mechanically robust and electrically and magnetically reliable so as to be operable even under harsh conditions.

In particular, testing the reliability of electrically conductive interconnections such as vias (vertical interconnection access) in a component carrier (preform), and thereby securing product quality and performance, remains a challenge.

Conventionally, electrically conductive connections can be electrically contacted, e.g. through a wire, by a respective measurement device. An established method may be the so-called four-wire-test (FWR) that can be used to accurately measure the electrical resistance of interconnections in a non-destructive manner. Hereby, the measurement device comprises four wires, wherein two wires are dedicated for measuring a current, while the other two wires are dedicated for determining a voltage. From the result, the resistance of the electrical connection under test may be obtained. The measured resistance may be used as an electric parameter to evaluate the quality of the electrically conductive connection.

Conventionally, the FWT method is performed using so-called daisy chain coupons. Even though the daisy chain coupons may detect completely defect electrically conductive interconnections (e.g. completely broken via with no remaining interface), the method may not be able to reliably detect weak interconnections such as partially broken vias (with reduced remaining interface). This may be because the resistance increase of such a weak interconnection can be very low compared to the resistance increase of a completely defect interconnection. Furthermore, the daisy chain method may provide only a result with respect to all the interconnections. Hence, the result of the daisy chain measurement will be that either all interconnections have sufficient quality, or that there is a defect in one of all the interconnections.

Additionally, through the daisy chain coupon the detectable defect is related to the electrically conductive interconnections (i.e. vias and/or the electrically connecting structures), any kind of interaction with a further structure cannot be estimated; for example, if the electrically conductive interconnection simulates an electrically conductive interconnection in contact/merging from a component, the defects deriving from the different materials, chemical properties, surfaces interaction, and different mechanical and/or thermal properties between the electrically conductive interconnection and the component.

Thus, it may be desirable to reliably measure individual electrically conductive interconnections in an accurate manner with respect to only weak defects as well.

### SUMMARY

There may be a need to test electrically conductive interconnections in a component carrier (preform) in an efficient, accurate, and reliable manner.

A component carrier and a method are provided.

According to a first aspect of the disclosure, there is described a component carrier (preform), comprising: a stack comprising at least two electrically conductive layer structures and at least one electrically insulating layer structure; a plurality of components provided in or on the stack; a plurality of electrically conductive interconnections in the stack electrically connecting at least one electrically conductive layer structure and a respective component; and a test region provided in a portion of the component carrier, said the test region comprising at least one test component and at least one second electrically conductive interconnection, said further component having the area where said second electrically conductive interconnection is connected with the same mechanical/chemical features and/or the same position in the depth of the correspondent one of said plurality of components, said second electrically conductive interconnection having the same mechanical/chemical features and/or the same position in the depth of at least one of said plurality of electrically conductive interconnections, wherein connecting areas are exposed on same side of the component carrier, said areas being respectively electrically connected to the two extremities of said at least one second electrically conductive interconnection.

According to a second aspect of the disclosure, there is described a method to check the quality of an electrically conductive interconnection of a component carrier, said component carrier comprising:—a plurality of components provided in or on the stack,—a plurality of said electrically conductive interconnections electrically connecting at least one electrically conductive layer structure and a respective component, and—at least a test region provided in a portion of the component carrier, said test region comprising at least one test component and at least one second electrically conductive interconnection, said further component having the area where said second electrically conductive interconnection is connected with the same mechanical/chemical features and/or the same position in the depth of the correspondent one of said plurality of components, said second electrically conductive interconnection having the same mechanical/chemical features and/or the same position in the depth of at least one of said plurality of electrically conductive interconnections, wherein the two extremities of said at least one second electrically conductive interconnection are connected to respective connecting areas exposed on same side of the component carrier, said method comprising the step of estimating the quality of the further electrically interconnection in function of at least one electrical value acquired from the two exposed areas.

### OVERVIEW OF EMBODIMENTS

The term “electrically conductive interconnection” may in this context denote an electrically conductive structure that is suitable to connect at least two electrically conductive (layer) structures (in a component carrier layer stack), wherein one of the electrically conductive (layer) structure is provided on a component. In a preferred example, an electrically conductive interconnection may be a vertical electrically conductive interconnection such as a blind via in a component carrier layer stack. These electrically conductive interconnections may be provided on an active area of the component carrier where the electrically conductive structures and one or more components may be connected or connectable one to each other through said electrically conductive interconnection.

A plurality of electrically conductive interconnections may be arranged in a layer stack.

The term “second electrically conductive interconnection” may in this context denote an electrically conductive interconnection provided on a different area of the component carrier, comprising comparable properties as the electrically conductive interconnections. In an example, the second electrically conductive interconnection may be arranged at a comparable/similar vertical (along z) position in the stack. In a further example, the electrically conductive interconnection comprises comparable/similar mechanical/electrical/chemical properties as the electrically conductive interconnection(s) and/or a comparable/similar geometry. In a preferred embodiment, all mentioned parameters may be comparable/similar.

The second electrically conductive interconnection may be suitable to be electrically tested with respect to an electric parameter (e.g. voltage, current, resistance), in particular by one or more wire(s) of a measurement apparatus.

The term “test component” may in this context denote a component, for an example a dummy component, provided on a different area of the component carrier, preferably in the test region, comprising comparable properties as at least one of the components, in particular that provided in an active area. In an example, the component may be arranged at a comparable/similar vertical (along z) position in the stack. In a further example the test component may have comparable/similar spatial dimensions as the component in the active area. In a further example, the test component comprises an area where the second electrically conductive interconnection is connected with the same mechanical/chemical features and/or the same position in the depth of the correspondent one of said plurality of components. In a preferred embodiment, all mentioned parameters may be comparable/similar.

In particular, the area where the second electrically conductive interconnection is connected has the same roughness and/or superficial tension of one of said plurality of components.

The term “test region” may in this context denote a region of the stack (or component carrier, depending on the design), wherein a measurement device, for example a four-wire-test measurement device or any further device to measure a(n) (electric) value (for example the electrically resistance) at a specific environment condition (for example at specific temperature, with specific electric values with specific repetitions on the test) of at least one second electrically conductive interconnection, may electrically contact the component carrier to perform the electrically conductive interconnection test, particularly according to the known requirements of reflow, hot oil, thermal cycling/stability, insulation resistance/bHAST tests.

To provide a reliable test of this second electrically conductive interconnection without affecting the functionality or the mechanical integrity of said electrically conductive interconnections and/or said electrically conductive structures and/or said plurality of components, at least one second electrically conductive interconnection may be provided on a test area (e.g. inside or outside the active area), having the same same mechanical/chemical features and/or the same position in the depth of the stack as the at least one of said electrically conductive interconnections and being connected to an area provided on the test component, connected with a test component provided in the same test area, having the area where said second electrically conductive interconnection is connected with the same mechanical/chemical features and/or the same position in the depth of the correspondent one of said plurality of components, allowing the test of the second electrically conductive interconnection and its interaction with the test component in the test region, i.e. without involving the interconnection and the components in the active area, and then preferably estimating the quality of the electrically conductive interconnections through this test.

The term “connection area” may in this context denote an electrically conductive area (e.g. a pad, a terminal, etc.) that is electrically connected to the second electrically conductive interconnection to be tested. Hence, via the connection area, the second electrically conductive interconnection may be electrically contacted, even though the second electrically conductive interconnection may be (fully) embedded in the stack. According to a further or additional embodiment, the connection area may be formed by a (discontinuous) electrically conductive layer structure arranged at the upper extremity of the respective electrically conductive interconnection(s). In another example (especially when the electrically conductive interconnection (arrangement) is buried in the stack), the connection area may be electrically connected to the second electrically conductive interconnection (arrangement) by additional interconnections such as vias. In a specific example, the connection area has a square shape, aimed for example to use as much available component carrier surface as possible; more specifically the square testing area of a connection area may be 1*1 mm (or smaller). In the present disclosure it is anyway not excluded the provisions of other shapes, such as circular, rectangular, or irregular shape. According to an alternative or additional embodiment of the present disclosure, the shape of the connection areas may be of different shape and/or of different dimensions and/or of different materials/color/roughness i.e. to clearly distinguish this connection area provided for the test reasons from other areas provided on the same side of the component carrier provided for other functions.

In an embodiment, the stack/component carrier surface may comprise a plurality of exposed connection areas, preferably arranged as an array. Thereby, a high number of second electrically conductive interconnections (arrangements) may be tested (individually) from the same component carrier side, even though at least some of them may be buried in the stack.

In the context of the present document, the term “same side of the component carrier” may particularly denote the same side, i.e. along the thickness direction, for that one of the two opposed main surfaces of the component carrier can be at least partially perpendicularly touched.

In a preferred embodiment the component carrier comprises a main body, i.e. a main stack only; in this preferred embodiment for “same side” it is meant the same main surface of the body/stack.

In an alternative embodiment, the component carrier comprises at least two bodies, i.e. a (stacked) PCB and a (stacked) substrate assembled on said PCB; in this embodiment, the term “same side of the component carrier” may mean the same side where the two main surfaces of the two bodies are at least partially reachable; on that purpose, the connecting areas can be provided both on one body, or the other body or in both bodies (in that case the second electrically conductive interconnection may be provided between the first and the second bodies).

In the context of the present document, the term “component carrier” may particularly denote any support structure which is capable of accommodating one or more components thereon and/or therein for providing mechanical support and/or electrical connectivity. In other words, a component carrier may be configured as a mechanical and/or electronic carrier for components. In particular, a component carrier may be one of a printed circuit board, an organic interposer, and an IC (integrated circuit) substrate. A component carrier may also be a hybrid board combining different ones of the above-mentioned types of component carriers.

The term “component carrier preform” may in particular refer to a component carrier under production, i.e. a semi-finished product. An example may be a panel that comprises a plurality of component carriers under manufacture, whereby the component carrier will be separated (singularization) after the manufacture process. Besides the component carriers under manufacture, the component carrier preform (panel) may further comprise separation areas in between the component carriers under manufacture, which separation areas will not form part of the final component carrier products anymore.

In the context of the present document, the term “component carrier” may encompass a discrete component carrier, a discrete component carrier preform, and a component carrier preform that comprises two or more component carriers under manufacture.

While in one example the connection areas may be arranged on component carriers under manufacture, in another example the connection areas may be arranged at the separation areas of a component carrier preform (panel). In the later example, the connection areas may thus not form part of the final component carrier product.

In an embodiment, the component carrier comprises a (layer) stack of at least one electrically insulating layer structure and at least one electrically conductive layer structure. For example, the component carrier may be a laminate of the mentioned electrically insulating layer structure(s) and electrically conductive layer structure(s), in particular formed by applying mechanical pressure and/or thermal energy. The mentioned stack may provide a plate-shaped component carrier capable of providing a large mounting surface for further components and being nevertheless very thin and compact. The term “layer structure” may particularly denote a continuous layer, a patterned layer or a plurality of non-consecutive islands within a common plane.

According to an example embodiment, the disclosure may be based on the idea that the quality of the electrically conductive interconnections in a component carrier (preform) and its interaction (i.e. connection) with a component can be estimated in an efficient, accurate, and reliable manner, when a specific architecture is provided, through the test of a second electrically conductive interconnection connected to a test component surface provided in a dedicated test region, without affecting the functionality or the mechanical integrity of said electrically conductive interconnections and/or said electrically conductive structures and/or said one or more components.

In particular, the connection areas may enable an easy and straightforward electrical contact with the (four) wires of a (four-wire-test) measurement device. Accordingly, the resistance of the second electrically conductive interconnection may be reliably determined, even though the electrically conductive interconnections may be buried in the layer stack. While conventional daisy chain approaches (see above) provide a result with regard to all interconnections and electrically conductive structures in (electrically) connection with said all interconnections, the described approach may provide individual results for the electrically conductive interconnections, so that defects may be detected more accurately and selectively. Further, in comparison to the conventional method, the described approach may provide more precise results that do not only detect completely defect interconnections (e.g. a complete break of the metal structure), but also weak interconnections, e.g. with partial breaks in the metal structure of the interconnection and also the interconnections (partial) defects of the electrically conductive interconnections with the respective component.

Furthermore, a statistical distribution of the measured electric parameter (in particular resistance) may be obtained to thereby provide a precise statement about the interconnection (processes) quality (e.g. a resistance map) of the component carrier.

### EXAMPLE EMBODIMENTS

In an embodiment, a conductive sub-area is provided on one of the main surfaces of the test component, at least one of said exposed connecting area being electrically connected to one extremity of said at least one second electrically conductive interconnection through said sub-area. Thereby, the conductive sub-area and the second electrically conductive interconnection simulate the respective component conductive sub-area (for example the connecting area and/or pad) and the electrically conductive interconnection, so that through the connection with the exposed connecting area the electrical measure of the second electrically conductive interconnection can be provided for a precise and reliable estimation of the quality of the respective electrically conductive interconnection.

According to a further embodiment, said exposed area is connected to said respective sub-area through a third electrically conductive interconnection. This may provide the advantage that even if one extremity of the second electrically conductive interconnection is buried in the component carrier stack, the connection of said extremity from the same exposed area of (or linked to) the other second electrically conductive interconnection extremity is possible with an easy and cheap solution, namely the provision of a third electrically conductive interconnection connecting the exposed area with the sub-area.

According to a further embodiment, a further exposed area is electrically connected the other extremity of said respective at least one second electrically conductive interconnection. Preferably, said exposed areas and further exposed areas are provided on the same side of the component carrier. This may provide the advantage that even if both extremities of the second electrically conductive interconnections are buried in the component carrier stack, the (electrical) measure of the second electrically conductive interconnection can be provided through two exposed areas provided on the same side of the component carrier.

According to a further embodiment, said further exposed area is connected to said other extremity through a fourth electrically conductive interconnection and/or through one of said at least two electrically conductive layer structures. This may provide the advantage that even if the extremity of the second electrically conductive interconnection is buried in the component carrier stack, the connection of said extremity from the exposed area is provided with an easy and cheap solution, namely the provision of a fourth electrically conductive interconnection connecting the exposed area with the second electrically conductive interconnection.

According to a further embodiment, wherein at least one of the two extremities of the second electrically conductive interconnection is connected to two areas exposed on the same main surface of the component carrier. This may provide the advantage that the result of the measurement using the measurement device is more accurate.

According to a further embodiment, each extremity of the second electrically conductive interconnection is connected to two areas exposed on the same main surface of the component carrier.

This may provide the advantage that specific tests involving different and preferably contemporaneous measures, such as the FWT involving a current and a voltage measure, can be done in a reliable way because the wires of one measure can be connected to two exposed areas each connected to a respective extremity of the second electrically conductive interconnection, whereas the wires of the other measure can be connected to the other two exposed areas each connected to a respective extremity of the second electrically conductive interconnection.

According to a further embodiment, a plurality of second electrically conductive interconnections is provided on the component carrier, said plurality of said second electrically conductive interconnections are provided in different positions with respect to the stack direction. The advantage of exposed areas on the same side of the component carrier allows the provision of second electrically conductive interconnections in different positions with respect to the stack direction (in the depth) of the stack, allowing the electrical contact with the respective extremities through the contact of the connected exposed areas. In other words, the position of the second electrically conductive interconnections does not affect their testing procedure due to the provision of the respective exposed area in the same side of the component carrier.

Each of said plurality of second electrically conductive interconnections may be provided on the same position, with respect to the stack direction, of correspondent electrically conductive interconnection(s) provided on the active region.

According to a further embodiment, a plurality of test components is provided, said plurality of test components are provided in different positions with respect to the stack direction. Consequently, the interaction between the electrically conductive interconnection and the component provided in the active area is simulated by the second electrically conductive interconnection and the test component in terms of its position in the stack direction, preferably reflecting the same procedural steps of the electrically conductive interconnection manufacturing, especially in a layer-to-layer manufacturing process.

Each of said plurality of test components may be provided on the same position, with respect to the stack direction, of corresponding component(s) provided on the active region.

According to a further embodiment, the exposed areas respectively connected to the plurality of said second electrically conductive interconnections have an array disposition on the main area of the component carrier. Thereby, a high number of second electrically conductive interconnections (arrangements) may be tested (individually) from the same component carrier side, even though at least some of them may be buried in the stack.

According to a further embodiment all the exposed connecting areas have the same surface. This may provide an immediate recognition by the operator of the testing area due to the specific resulting pattern.

According to a further embodiment the exposed connecting areas are quadrangularly-shaped. This shape provides the advantage of an improvement of the areas where the wires/testing contacting element assures the electrical contact between the measurement device and the second electrically conductive interconnection extremity.

According to a further embodiment, a group of test components, the respective second electrically conductive interconnections and the respective exposed connecting areas are repeatedly provided in the test region, preferably along a linear direction. This may have the advantage that the measurement device performs a (electrical) measures more efficiently.

In particular, the second electrically conductive interconnections, the test components and the exposed connecting areas of one group are identical and are provided in the same position in the layer depth with respect to those of the other groups.

This provides an advantageous statistical and reliable interconnection quality estimation due to the bundle of (electrical) measures done for several second electrically conductive interconnections having the same features/positions and interaction with the respective test component.

According to a further embodiment, several sub-arrays of respective exposed connecting areas are provided on the external main surface of the component carrier. This provides the advantage of an improved estimation of the quality of the electrically conductive interconnections (preferably those in the active area) through the (electrical) measurement and the quality estimation of the second electrically conductive interconnections provided in proximity of an area (and in the closer conditions within the component carrier) where said electrically conductive interconnections are provided.

According to a further embodiment, a plurality of said second electrically conductive interconnection are connected on the same side of the test component, said plurality of said second electrically conductive interconnection being connected in series so that each of said plurality of said second electrically conductive interconnection is connected to a first close second electrically conductive interconnection through a sub-area provided on one of the main surfaces of the test component and to a second close second electrically conductive interconnection through a portion of one of said at least two electrically conductive layer structures, forming a Daisy Chain structure. This circumstance may directly result from a reliable quality estimation of the interaction between the second electrically conductive interconnections and the test component through a Daisy Chain structure.

According to a further embodiment, each of the two electrical extremities of said Daisy Chain structure is electrically connected to one of said exposed connecting areas, simplifying the test of the Daisy Chain structure.

According to a further embodiment, at least one of the two electrical extremities of said Daisy Chain structure is electrically connected to one of said exposed connecting areas. This configuration also provides a structure suitable to check the interaction quality between the second electrically conductive interconnections and the test component using specific measurement device such as the FWT in combination with the Daisy Chain test structure.

According to a further embodiment, said at least one second electrically conductive interconnection comprises a one of a blind via, a through via, a plated through hole, an interconnection between component carriers, a wire, a nanowire, a sputtered material, a solder material, an electrically conductive adhesive.

In an embodiment, a plurality of second electrically conductive interconnections is provided and stacked one to each other in the stack.

According to a further embodiment, the material of the surface of said test component where said second electrically conductive interconnection is connected is the same as the material of the surface of the component where said electrically conductive interconnection is connected. This improves the degree of simulation of the interaction between the second electrically conductive interconnections and the test component with respect to the close electrically conductive interconnections and the component, preferably provided in the active area.

According to a further embodiment, the connection interface between the test component and the respective second electrically conductive interconnection is the same as the connection interface between the respective component and the respective electrically conductive interconnection, improving the degree of simulation of the respective interaction.

More in particular, as for the same connection interface it is meant the similar, preferably the same, shapes and/or roughness and/or dimensions and/or positions (i.e. along the stack direction) and/or structure (i.e. specific layers) and/or process step).

According to a further embodiment, said electrical value acquired from the two exposed areas comprises voltage or current intensity.

According to a further embodiment, the value estimated by the acquired electrical value is the electrical resistance.

According to a further embodiment, a plurality of second electrically conductive interconnections and a plurality of exposed areas are provided, the two extremities of each second electrically conductive interconnection being connected with two of said exposed areas, the method comprising the step of estimating the quality of each further electrically interconnection as a function of at least one electrical value (preferably the resistance and/or inductive reactance (of inductors) and/or the capacitive reactance (of capacitors)) acquired from the respective exposed areas.

According to a further embodiment, a plurality of second electrically conductive interconnections are connected on the same side of the test component, said plurality of said second electrically conductive interconnection being connected in series so that each of said plurality of said second electrically conductive interconnection is connected to a first close second electrically conductive interconnection through a sub-area provided on one of the main surfaces of the test component and to a second close second electrically conductive interconnection through a portion of one of said at least two electrically conductive layer structures, forming a Daisy Chain structure, said method comprising the step of estimating the quality of the further electrically interconnections as a function of at least one electrical value acquired from the two extremities of said Daisy Chain structure.

This circumstance may directly result from a reliable quality estimation of the interaction between the second electrically conductive interconnections and the test component through a Daisy Chain structure.

According to a further embodiment, said component carrier comprises several test regions on the [common] main surface, the method further comprising a carrier quality evaluation step, estimating the quality of the electrically conductive interconnections in the (active regions of) component carrier based on the estimated quality of the second electrically conductive interconnections of the several test regions.

This method provides a reliable quality estimation of the electrically conductive interconnections without interacting with the electrically conductive interconnections in the active region.

In an embodiment, the component carrier is shaped as a plate. This contributes to the compact design, wherein the component carrier nevertheless provides a large basis for mounting components thereon. Furthermore, in particular, a naked die as an example of an embedded electronic component, can be conveniently embedded, thanks to its small thickness, into a thin plate such as a printed circuit board.

In an embodiment, the component carrier is configured as one of the group consisting of a printed circuit board, a substrate (in particular an IC substrate), and an interposer.

In the context of the present application, the term “printed circuit board” (PCB) may particularly denote a plate-shaped component carrier which is formed by laminating several electrically conductive layer structures with several electrically insulating layer structures, for instance by applying pressure and/or by the supply of thermal energy. As preferred materials for PCB technology, the electrically conductive layer structures are made of copper, whereas the electrically insulating layer structures may comprise resin and/or glass fibers, so-called prepreg or FR4 material. The various electrically conductive layer structures may be connected to one another in a desired way by forming holes through the laminate, for instance by laser drilling or mechanical drilling, and by partially or fully filling them with electrically conductive material (in particular copper), thereby forming vias or any other through-hole connections. The filled hole either connects the whole stack, (through-hole connections extending through several layers or the entire stack), or the filled hole connects at least two electrically conductive layers, called via. Similarly, optical interconnections can be formed through individual layers of the stack in order to receive an electro-optical circuit board (EOCB). Apart from one or more components which may be embedded in a printed circuit board, a printed circuit board is usually configured for accommodating one or more components on one or both opposing surfaces of the plate-shaped printed circuit board. They may be connected to the respective main surface by soldering. A dielectric part of a PCB may be composed of resin with reinforcing fibers (such as glass fibers).

In the context of the present application, the term “substrate” may particularly denote a small component carrier. A substrate may be a, in relation to a PCB, comparably small component carrier onto which one or more components may be mounted and that may act as a connection medium between one or more chip(s) and a further PCB. For instance, a substrate may have substantially the same size as a component (in particular an electronic component) to be mounted thereon (for instance in case of a Chip Scale Package (CSP)). In another embodiment, the substrate may be substantially larger than the assigned component (for instance in a flip chip ball grid array, FCBGA, configuration). More specifically, a substrate can be understood as a carrier for electrical connections or electrical networks as well as component carrier comparable to a printed circuit board (PCB), however with a considerably higher density of laterally and/or vertically arranged connections. Lateral connections are for example conductive paths, whereas vertical connections may be for example drill holes. These lateral and/or vertical connections are arranged within the substrate and can be used to provide electrical, thermal and/or mechanical connections of housed components or unhoused components (such as bare dies), particularly of IC chips, with a printed circuit board or intermediate printed circuit board. Thus, the term “substrate” also includes “IC substrates”. A dielectric part of a substrate may be composed of resin with reinforcing particles (such as reinforcing spheres, in particular glass spheres).

The substrate or interposer may comprise or consist of at least a layer of glass, silicon (Si) and/or a photoimageable or dry-etchable organic material like epoxy-based build-up material (such as epoxy-based build-up film) or polymer compounds (which may or may not include photo- and/or thermosensitive molecules) like polyimide or polybenzoxazole.

In an embodiment, the at least one electrically insulating layer structure comprises at least one of the group consisting of a resin or a polymer, such as epoxy resin, cyanate ester resin, benzocyclobutene resin, bismaleimide-triazine resin, polyphenylene derivate (e.g. based on polyphenylenether, PPE), polyimide (PI), polyamide (PA), liquid crystal polymer (LCP), polytetrafluoroethylene (PTFE) and/or a combination thereof. Reinforcing structures such as webs, fibers, spheres or other kinds of filler particles, for example made of glass (multilayer glass) in order to form a composite, could be used as well. A semi-cured resin in combination with a reinforcing agent, e.g. fibers impregnated with the above-mentioned resins is called prepreg. These prepregs are often named after their properties e.g. FR4 or FR5, which describe their flame-retardant properties. Although prepreg particularly FR4 are usually preferred for rigid PCBs, other materials, in particular epoxy-based build-up materials (such as build-up films) or photoimageable dielectric materials, may be used as well. For high frequency applications, high-frequency materials such as polytetrafluoroethylene, liquid crystal polymer and/or cyanate ester resins, may be preferred. Besides these polymers, low temperature cofired ceramics (LTCC) or other low, very low or ultra-low DK materials may be applied in the component carrier as electrically insulating structures.

In an embodiment, the at least one electrically conductive layer structure comprises at least one of the group consisting of copper, aluminum, nickel, silver, gold, palladium, tungsten, magnesium, carbon, (in particular doped) silicon, titanium, and platinum. Although copper is usually preferred, other materials or coated versions thereof are possible as well, in particular, a material coated with supra-conductive material or conductive polymers, such as graphene or poly (3,4-ethylenedioxythiophene) (PEDOT), respectively.

At least one further component may be embedded in and/or surface mounted on the stack. The component and/or the at least one further component can be selected from a group consisting of an electrically non-conductive inlay, an electrically conductive inlay (such as a metal inlay, preferably comprising copper or aluminum), a heat transfer unit (for example a heat pipe), a light guiding element (for example an optical waveguide or a light conductor connection), an electronic component, or combinations thereof. An inlay can be for instance a metal block, with or without an insulating material coating (IMS-inlay), which could be either embedded or surface mounted for the purpose of facilitating heat dissipation. Suitable materials are defined according to their thermal conductivity, which should be at least 2 W/mK. Such materials are often based, but not limited to metals, metal-oxides and/or ceramics as for instance copper, aluminum oxide (Al₂O₃) or aluminum nitride (AlN). In order to increase the heat exchange capacity, other geometries with increased surface area are frequently used as well. Furthermore, a component can be an active electronic component (having at least one p-n-junction implemented), a passive electronic component such as a resistor, an inductance, or capacitor, an electronic chip, a storage device (for instance a DRAM or another data memory), a filter, an integrated circuit (such as field-programmable gate array (FPGA), programmable array logic (PAL), generic array logic (GAL) and complex programmable logic devices (CPLDs)), a signal processing component, a power management component (such as a field-effect transistor (FET), metal-oxide-semiconductor field-effect transistor (MOSFET), complementary metal-oxide-semiconductor (CMOS), junction field-effect transistor (JFET), or insulated-gate field-effect transistor (IGFET), all based on semiconductor materials such as silicon carbide (SiC), gallium arsenide (GaAs), gallium nitride (GaN), gallium oxide (Ga₂O₃), indium gallium arsenide (InGaAs), indium phosphide (InP) and/or any other suitable inorganic compound), an optoelectronic interface element, a light emitting diode, a photocoupler, a voltage converter (for example a DC/DC converter or an AC/DC converter), a cryptographic component, a transmitter and/or receiver, an electromechanical transducer, a sensor, an actuator, a microelectromechanical system (MEMS), a microprocessor, a capacitor, a resistor, an inductance, a battery, a switch, a camera, an antenna, a logic chip, and an energy harvesting unit. However, other components may be embedded in the component carrier. For example, a magnetic element can be used as a component. Such a magnetic element may be a permanent magnetic element (such as a ferromagnetic element, an antiferromagnetic element, a multiferroic element or a ferrimagnetic element, for instance a ferrite core) or may be a paramagnetic element. However, the component may also be an IC substrate, an interposer or a further component carrier, for example in a board-in-board configuration. The component may be surface mounted on the component carrier and/or may be embedded in an interior thereof. Moreover, other components, in particular those which generate and emit electromagnetic radiation and/or are sensitive with regard to electromagnetic radiation propagating from an environment, may be used as a component.

In an embodiment, the component carrier is a laminate-type component carrier. In such an embodiment, the component carrier is a compound of multiple layer structures which are stacked and connected together by applying a pressing force and/or heat.

After processing interior layer structures of the component carrier, it is possible to cover (in particular by lamination) one or both opposing main surfaces of the processed layer structures symmetrically or asymmetrically with one or more further electrically insulating layer structures and/or electrically conductive layer structures. In other words, a build-up may be continued until a desired number of layers is obtained.

After having completed formation of a stack of electrically insulating layer structures and electrically conductive layer structures, it is possible to proceed with a surface treatment of the obtained layers structures or component carrier.

In particular, an electrically insulating solder resist may be applied to one or both opposing main surfaces of the layer stack or component carrier in terms of surface treatment. For instance, it is possible to form such a solder resist on an entire main surface and to subsequently pattern the layer of solder resist so as to expose one or more electrically conductive surface portions which shall be used for electrically coupling the component carrier to an electronic periphery. The surface portions of the component carrier remaining covered with solder resist may be efficiently protected against oxidation or corrosion, in particular surface portions containing copper.

It is also possible to apply a surface finish selectively to exposed electrically conductive surface portions of the component carrier in terms of surface treatment. Such a surface finish may be an electrically conductive cover material on exposed electrically conductive layer structures (such as pads, conductive tracks, etc., in particular comprising or consisting of copper) on a surface of a component carrier. If such exposed electrically conductive layer structures are left unprotected, then the exposed electrically conductive component carrier material (in particular copper) might oxidize, making the component carrier less reliable. A surface finish may then be formed for instance as an interface between a surface mounted component and the component carrier. The surface finish has the function to protect the exposed electrically conductive layer structures (in particular copper circuitry) and enable a joining process with one or more components, for instance by soldering. Examples for appropriate materials for a surface finish are Organic Solderability Preservative (OSP), Electroless Nickel Immersion Gold (ENIG), Electroless Nickel Immersion Palladium Immersion Gold (ENIPIG), Electroless Nickel

Electroless Palladium Immersion Gold (ENEPIG), gold (in particular hard gold), chemical tin (chemical and electroplated), nickel-gold, nickel-palladium, etc. Also nickel-free materials for a surface finish may be used, in particular for high-speed applications. Examples are ISIG (Immersion Silver Immersion Gold), and EPAG (Electroless Palladium Autocatalytic Gold).

### BRIEF DESCRIPTION OF THE DRAWINGS

The aspects defined above and further aspects of the disclosure are apparent from the examples of embodiment to be described hereinafter and are explained with reference to these examples of embodiment.

FIG. 1 illustrates a second electrically conductive interconnection in a test region according to an example embodiment of the disclosure.

FIG. 2 illustrates a cross-section of a test region according to an example embodiment of the disclosure.

FIG. 3 illustrates a top view on the test region with connection areas according to example embodiments of the disclosure.

FIG. 4 illustrates a top view of the component carrier with active regions and test regions according to example embodiments of the disclosure.

FIG. 5 illustrates a top view of the test region according to a further embodiment, with connection areas according to example embodiments of the disclosure.

FIG. 6 illustrates a cross-section of a test region according to an example embodiment of the disclosure according to a further example embodiment of the disclosure.

### DETAILED DESCRIPTION OF THE ILLUSTRATED EMBODIMENTS

The illustrations in the drawings are schematically presented. It is noted that in different figures, similar or identical elements or features are provided with the same reference signs or with reference signs, which are different from the corresponding reference signs only within the first digit. In order to avoid unnecessary repetitions elements or features which have already been elucidated with respect to a previously described embodiment are not elucidated again at a later position of the description.

Further, spatially relative terms, such as “front” and “back”, “upper” and “lower”, “left” and “right”, et cetera are used to describe an element's relationship to other element(s) as illustrated in the figures. Thus, the spatially relative terms may apply to orientations in use which differ from the orientation depicted in the figures. Obviously, all such spatially relative terms refer to the orientation shown in the figures only for ease of description and are not necessarily limiting.

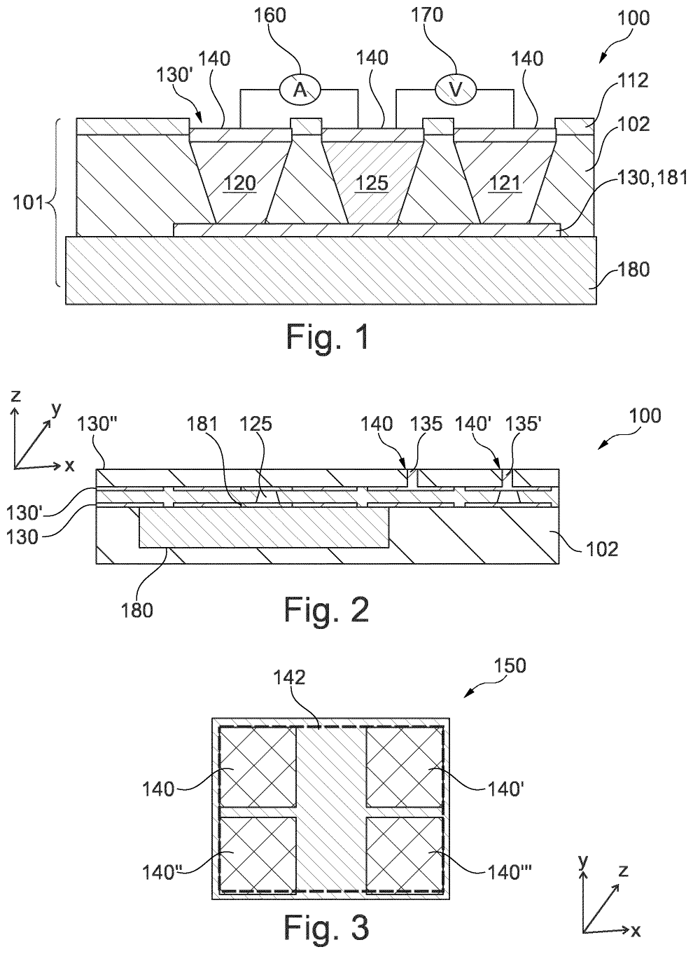

FIG. 1 illustrates a cross-sectional view of a section of test region 150 of a component carrier 100 comprising a layer stack 101 comprising two electrically conductive layer structures 130, 130′ and one electrically insulating layer structure 102 according to an example embodiment of the disclosure. Said electrically insulating layer structure 102 may comprise reinforcing material e.g. glass fibers and/or glass spheres. Moreover, said electrically insulating layer structure 102, which is exposed on the surface of the component carrier, may comprise a surface finish 112, e.g. solder resist. Said two electrically conductive layer structures 130, 130′ may be vertically interconnected by a plurality, in particular three, electrically conductive interconnections 120, 121, 125.

Particularly, one of the three electrically conductive interconnections, hereinafter named second conductive interconnection 125, may be provided with the same mechanical/chemical features and/or the same position in the depth of at least one of said plurality of electrically conductive interconnections provided in an active area 200 as below described. Said second electrically conductive interconnection 125 may be configured as a blind via, e.g. formed by laser drilling which manufacturing method results in the tapered shape. The upper part of the second electrically conductive interconnection 125 is termed “first extremity”. In this example the first extremity is configured as a connecting area 140 and is exposed on the main surface of said component carrier 100. Said connection area 140 may comprise a surface finish, e.g. ENIPEG, 112. In another example the first extremity may be embedded in the layer stack 101. The lower part of the second electrically conductive interconnection 125 is opposite to the first extremity and is termed “second extremity”. Said second extremity may be (electrically) connected to a sub-area and embedded in the layer stack 101.

Said sub-area may be (electrically) connected by at least one, in this example three, connecting areas (connecting areas and/or further connecting area and/or other connecting area) 140 to the (exposed) main surface of the same side of the layer stack 101 and may be (electrically) connected to a test component 180. Said test component 180 may have the area, where said second electrically conductive interconnection 125 is connected, with the same mechanical/chemical features and/or the same position in the depth of a correspondent component provided in an active area 200 as below described.

Schematically shown in FIG. 1 is a measurement device 160, 170, i.e. for a four-wire test, comprising four connecting wires that are moved to put in contact with the exposed areas 140 connected to the three electrically conductive interconnections 120, 121, 125 for the test of the second electrically conductive interconnection 125. In particular, there are a first wire and a second wire of a current measurement device (e.g. ammeter/amperemeter) 160 respectively connected to an exposed area and a further exposed area and a third and a fourth wire of a voltage measurement device (e.g. voltmeter) 170 respectively connected to said further and another exposed area.

Due to the fact that the second electrically conductive interconnection 125 has the first extremity aligned and/or exposed to the main surface of the component carrier, a respective one of both the current measurement device 160 and the voltage measurement device 170 are directly put in connection with this first extremity. On the other hand, being the second extremity of said second electrically conductive interconnection 125 embedded in the component carrier 100, the connection with the respective further wires of the current measurement device 160 and the voltage measurement device 170 is provided through the electrical connection of the sub-area with the second extremity and with one of the other two electrically conductive interconnections 120, 121, each of those preferably having one extremity exposed to the same component carrier main surface where the first extremity of the second electrically conductive interconnection 125 is exposed, then resulting to the exposure of all the surfaces needed to connect the wires of the measurement device 160, 170 on the same area of the component carrier 100, to provide the electrical connection with both extremities of the second electrically conductive interconnection 125.

Due to the interaction of the second extremity with the surface of the test component 180, the features of the second electrically conductive interconnection 125 simulate all the features of one or a plurality of electrically conductive interconnections provided in an active area 200, as below described.

FIG. 2 illustrates another cross-sectional view of a test region 150 of a component carrier 100 as a further exemplary embodiment. Differently from the previous embodiment, the second electrically conductive interconnection 125 is fully embedded/buried in the component carrier, so that also the upper extremity cannot be directly exposed through the exposed area. In this example three electrically conductive layer structures 130, 130′, 130″ are provided on three different component carrier positions above a main surface of the test component 180. Particularly, at least a portion of (the bottom) one of the three of electrically conductive layer structures 130 is in contact with a surface of the test component 180, providing the connection with the second extremity of the second electrically conductive interconnection 125. On the other hand, at least a portion of the intermediate one of the three electrically conductive layer structures 130′ is connected to the first extremity of the second electrically conductive interconnection 125. Moreover, the upper one of the three electrically conductive layer structures 130″ comprises at least two exposed areas (not connected among each other).

In the shown embodiment, the connection between the first extremity of the second electrically conductive interconnection 125 and one of the exposed areas 140 is preferably provided through a (further) electrically conductive interconnection (i.e. a via) 135 preferably connecting the intermediate electrically conductive layer structure 130′ (i.e. connected to the upper extremity of the second electrically conductive interconnection 125) to the upper electrically conductive layer structure 130″ (i.e. connected to one of the exposed areas 140).

According to a further embodiment, the connection between the second extremity of the second electrically conductive interconnection 125 and the other one of the exposed area 140′ is provided through (further) electrically conductive interconnections (i.e. a via) 135′ connecting the bottom electrically conductive layer structure 130 (i.e. connected to the bottom extremity of the second electrically conductive interconnection 125) to the upper electrically conductive layer structure 130′ (i.e. connected to the other one of the exposed areas 140′).

Even if the second electrically conductive interconnection 125 is fully buried in the component carrier 100, the exposure of all the surfaces needed to connect the wires of the measurement device 160, 170 on the same area of the component carrier 100 allows the electrical connection with both extremities of the second electrically conductive interconnection 125.

FIG. 3 illustrates a top view of a test region 150 according to a preferred example embodiment of the solution disclosed in FIG. 2. In this example, the two extremities of the second electrically conductive interconnection 125 are each connected to two exposed areas 140, 140′. Preferably, the electrically conductive layer structures 130 and the (further) electrically conductive interconnections 135 are configured to connect the exposed areas 140 and 140′ with the first extremity of the second electrically conductive interconnection 125 and to connect the exposed areas 140″ and 140′″ to the second extremity of the second electrically conductive interconnection 125.

As shown in FIG. 3, said four exposed areas 140, 140′, 140″, 140′″ preferably have an array disposition 142 on the main surface area of the component carrier 100, preferably each comprising a quadrangularly-shaped connection area. Each element of said array 142 (connection area, further connection area, other connection area) may have similar/same mechanical/chemical features.

By connecting said first and second wire of said current measurement device 160 and said third and fourth wire of said voltage measurement device 170 to each one of said connection areas 140 so that each of both the current measurement device 160 and voltage measurement device 170 are electrically connected to both the extremities of the second electrically conductive interconnection 125, the quality of said second electrically conductive interconnection 125 in function of at least one electrical value may be acquired.

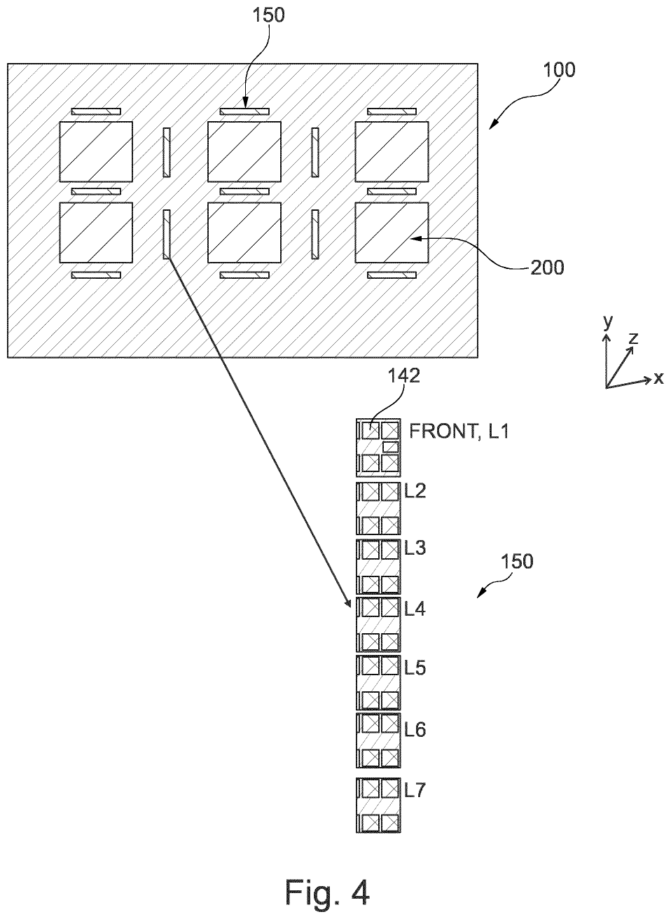

FIG. 4 illustrates a top view of a component carrier 100 according to another embodiment. In this example the component carrier 100 comprises a plurality, in particular six, active regions 200, each comprising a stack comprising at least two electrically conductive layer structures and at least one electrically insulating layer structure, a plurality of components provided in or on the stack and a plurality of electrically conductive interconnections in the stack. Said active region 200 may be exposed to the main surface of the component carrier 100. Additionally and/or alternatively, said active region 200 may be embedded in the stack. Said component carrier 100 further comprises a plurality, in particular thirteen, test regions 150, each in close spatial proximity to at least one active region 200. Each of said plurality of test regions 150 preferably comprises an array 142 of exposed areas 140 as shown in FIG. 4 (see detailed view below) that are seven repetitions (L1 to L7) of the exposed areas 140 of FIG. 3. This improves, from a statistical point of view, the quality evaluation of the electrically conductive interconnections in the active areas in proximity of this array 142.

Each of said plurality of test regions 150 preferably comprises at least one test component 180 and at least one second electrically conductive interconnection 125, said test component 180 having the area where said second electrically conductive interconnection 125 is connected with the same mechanical/chemical features and/or the same position in the depth of the correspondent one of said plurality of components in the proximate active area portion 140, said second electrically conductive interconnection 125 having the same mechanical/chemical features and/or the same position in the depth of at least one of said plurality of electrically conductive interconnections provided in the proximate active area portion. Consequently, the electrical measurement of the second electrically conductive interconnection 125 and the related quality/integrity estimation is used to evaluate the quality/integrity of the electrically conductive interconnection(s) provided in the proximate active area portion.

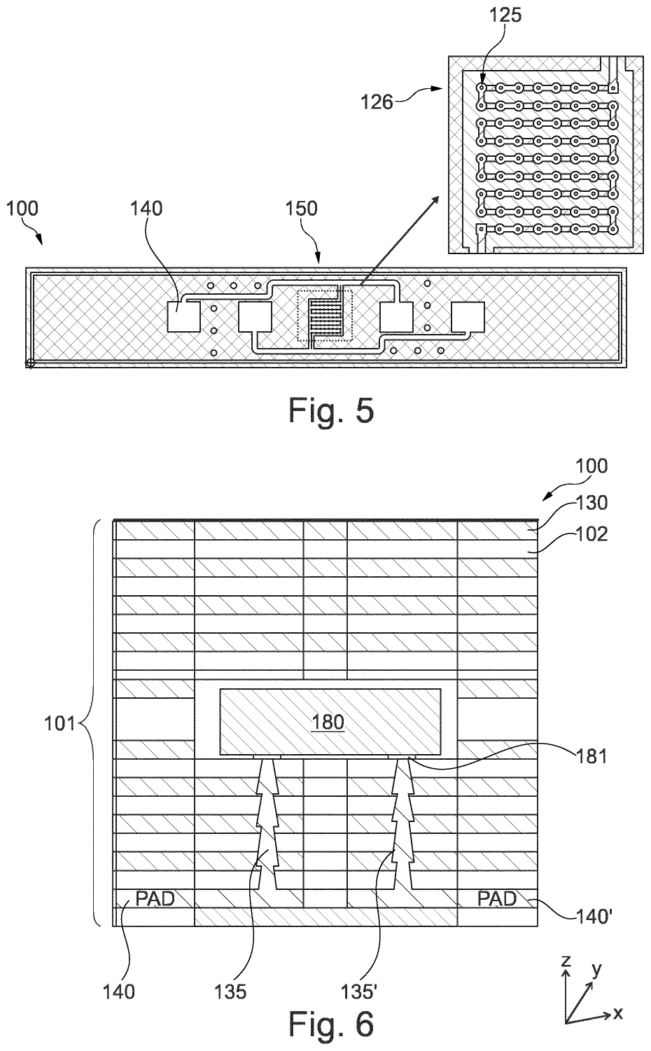

FIG. 5 illustrates a further top view of a test region 150 of a component carrier 100 according to a further embodiment. Differently from FIG. 3, the test region 150 comprises a Daisy Chain structure 126 comprising a plurality of second electrically conductive interconnections 125 appropriately connected as subsequently described. Said Daisy Chain structure 126, which could be seen in the enlarged view, may be (electrically) connected to a plurality, in particular four, connecting areas 140 through a second electrically interconnection and/or a third electrically interconnection and/or a fourth electrically interconnection, respectively. In this example, said Daisy Chain structure 126 may be embedded in the stack.

In an alternative example, said Daisy chain structure 126 may be exposed on the (main) surface of the stack 101. In this example, said Daisy Chain structure 126 may comprise a plurality of said second electrically conductive interconnection 125 connected on the same side of the test component 180, said plurality of said second electrically conductive interconnections 125 being connected in series so that each of said plurality of said second electrically conductive interconnection 125 is connected to a first close second electrically conductive interconnection through a sub-area provided on one of the main surfaces of the test component 180 and to a second close second electrically conductive interconnection through a portion of one [of said at least two] electrically conductive layer structures.

FIG. 6 illustrates another cross-sectional view of a test region 150 of a component carrier 100 according to an example embodiment. In addition to FIG. 2 the stack 101 comprises ten further electrically conductive layer structures 130 and nine electrically insulating layer structures 102. A test component 180 is embedded in the stack 101 located in the centre in stack thickness direction of said stack sandwiched between a plurality of further electrically conductive layer structures 130 and electrically insulating layer structures 102, respectively. Said test component 180 is (electrically) connected to a connection area 140, and/or further connection area 140′, and/or other connection areas exposed on a (main) surface through a plurality, in particular two, series of third electrically conductive interconnections 135 and/or fourth electrically interconnections 135′ and/or further electrically layer structures 130′.

REFERENCE SIGNS
100 component carrier
101 stack
102 electrically insulating layer structure
112 surface finish
120 electrically conductive interconnection
121 further electrically conductive interconnection
125 second electrically conductive interconnection
126 daisy chain structure
130 electrically conductive layer structure
135 third electrically conductive interconnection
135′ fourth electrically conductive interconnection
140 connecting area, exposed area
140′ further connecting area, further exposed area
142 array
150 test region
160 current measurement device
170 voltage measurement device
180 test component
181 conductive sub-area

1. A component carrier, comprising:
a stack comprising at least two electrically conductive layer structures and at least one electrically insulating layer structure;
a plurality of components provided in or on the stack;
a plurality of electrically conductive interconnections in the stack electrically connecting at least one electrically conductive layer structure and a respective component; and
a test region provided in a portion of the component carrier, the test region comprising at least one test component and at least one second electrically conductive interconnection,
the test component having the area where the second electrically conductive interconnection is connected with the same mechanical/chemical features and/or the same position in the depth of the correspondent one of the plurality of components,
the second electrically conductive interconnection having the same mechanical/chemical features and/or the same position in the depth of at least one of the plurality of electrically conductive interconnections,
wherein connecting areas are exposed on the same side of the component carrier,
the areas being respectively electrically connected to the two extremities of the at least one second electrically conductive interconnection.

2. The component carrier according to claim 1, wherein a conductive sub-area is provided on one of the main surfaces of the test component, at least one of the exposed connecting area being electrically connected to one extremity of the at least one second electrically conductive interconnection through the sub-area.

3. The component carrier according to claim 2, wherein the exposed area is connected to the respective sub-area through a third electrically conductive interconnection.

4. The component carrier according to claim 2, wherein a further exposed area is electrically connected the other extremity of the respective at least one second electrically conductive interconnection.

5. The component carrier according to claim 4, wherein the further exposed area is connected to the other extremity through a fourth electrically conductive interconnection and/or through one of the at least two electrically conductive layer structures.

6. The component carrier according to claim 1, wherein at least one of the two extremities of the second electrically conductive interconnection is connected to two areas exposed on the same main surface of the component carrier.

7. The component carrier according to claim 6, wherein each extremity of the second electrically conductive interconnection is connected to two areas exposed on the same main surface of the component carrier.

8. The component carrier according to claim 1, wherein a plurality of second electrically conductive interconnections is provided on the component carrier, the plurality of the second electrically conductive interconnections are provided in different positions with respect to the stack direction.

9. The component carrier according to claim 1, wherein the exposed areas respectively connected to the plurality of the second electrically conductive interconnections have an array disposition on the main area of the component carrier.

10.-11. (canceled)

12. The component carrier according to claim 1, wherein a group of test components, the respective second electrically conductive interconnections and the respective exposed connecting areas are repeatedly provided in the test region, preferably along a linear direction.

13. The component carrier according to claim 1, wherein several sub-arrays of respective exposed connecting areas are provided on the external main surface of the component carrier.

14. The component carrier according to claim 1, wherein a plurality of the second electrically conductive interconnections are connected on the same side of the test component, the plurality of the second electrically conductive interconnection being connected in series, such that each of the plurality of the second electrically conductive interconnections is connected to a first close second electrically conductive interconnection through a sub-area provided on one of the main surfaces of the test component and to a second close second electrically conductive interconnection through a portion of one of the at least two electrically conductive layer structures, forming a Daisy Chain structure.

15.-16. (canceled)

17. The component carrier according to claim 1, wherein the at least one second electrically conductive interconnection comprises a one of a blind via, a through via, a plated through hole, an interconnection between component carriers, a wire, a nanowire, a sputtered material, a solder material, an electrically conductive adhesive.

18. The component carrier according to claim 1, wherein the material of the surface of the test component where the second electrically conductive interconnection is connected is of the same material of the surface of the component where said electrically conductive interconnection is connected.

19. The component carrier according to claim 1, wherein the connection interface between the test component and the respective second electrically conductive interconnection is of the same material of the connection interface between the respective component and the respective electrically conductive interconnection.

20. A method to check the quality of an electrically conductive interconnection of a component carrier,
the method, comprising:
providing a component carrier comprising:
a plurality of components provided in or on the stack, and
a plurality of the electrically conductive interconnections electrically connecting at least one electrically conductive layer structure and a respective component, and
at least a test region provided in a portion of the component carrier, the test region comprising at least one test component and at least one second electrically conductive interconnection, said the further component having the area where the second electrically conductive interconnection is connected with the same mechanical/chemical features and/or the same position in the depth of the correspondent one of the plurality of components, the second electrically conductive interconnection having the same mechanical/chemical features and/or the same position in the depth of at least one of the plurality of electrically conductive interconnections,
wherein the two extremities of the at least one second electrically conductive interconnection are connected to respective connecting areas exposed on the same side of the component carrier, and
estimating the quality of the second electrically interconnection as a function of at least one electrical value acquired from the two exposed areas.

21.-22. (canceled)

23. The method according to claim 16, wherein a plurality of second electrically conductive interconnections and a plurality of exposed areas are provided, the two extremities of each second electrically conductive interconnection being connected with two of the exposed areas, the method comprising the step of estimating the quality each further electrically interconnection in function of at least one electrical value acquired from the respective exposed areas.

24. The method according to claim 16, wherein a plurality of second electrically conductive interconnections are connected on the same side of the test component, the plurality of the second electrically conductive interconnection being connected in series so that each of the plurality of the second electrically conductive interconnection is connected to a first close second electrically conductive interconnection through a sub-area provided on one of the main surfaces of the test component and to a second close second electrically conductive interconnection through a portion of one of the at least two electrically conductive layer structures, forming a Daisy Chain structure, the method comprising the step of estimating the quality of the further electrically interconnections as a function of at least one electrical value acquired from the two extremities of the Daisy Chain structure.

25. The method according to claim 16, wherein the quality estimation of each electrically interconnection is affected by the estimated quality of the second electrically conductive interconnection having the same mechanical/chemical features and/or the same position, belonging to the closest test region.

26. The method according to claim 16, wherein the component carrier comprises several test regions on the common main surface,
the method further comprising a carrier quality evaluation step, estimating the quality of the electrically conductive interconnections in the component carrier based to the estimated quality of the second electrically conductive interconnections of the several test regions.
